(19) United States
(12) Patent Application Publication
(10) Pub. No.: US 2026/0186599 A1
(43) Pub. Date: Jul. 2, 2026

(54) TOUCH SENSOR DRIVING CIRCUIT AND DISPLAY DEVICE INCLUDING THE SAME

(71) Applicant: LG DISPLAY CO., LTD., Seoul (KR)

(72) Inventors: Sung Chul KIM, Paju-si (KR); Nam Yong GONG, Paju-si (KR); Hoon Bae KIM, Paju-si (KR); Sun Yeop KIM, Paju-si (KR); Sung Jin Kang, Paju-si (KR); Jong Sung KIM, Paju-si (KR)

(73) Assignee: LG DISPLAY CO., LTD., Seoul (KR)

(21) Appl. No.: 19/396,076

(22) Filed: Nov. 20, 2025

(30) Foreign Application Priority Data
Dec. 27, 2024 (KR) 10-2024-0197855

(51) Int. Cl. G06F 3/041; G06F 3/044

(52) U.S. Cl. CPC G06F 3/04164; G06F 3/0446

(57) ABSTRACT

A touch sensor driving circuit includes a driving circuit for applying a driving signal to first touch electrodes arranged in a display area through a plurality of TX wires; and a sensing circuit for sensing voltages of second touch electrodes arranged in first and second regions within the display area through first and second RX wires, respectively, the voltages being generated by the driving signal. The sensing circuit may amplify or integrate a voltage difference between a voltage sensed through one n^{th} (where n is a natural number) RX wire positioned closest to TX wires located at opposite outermost sides of the plurality of TX wires and a second reference voltage, and amplify or integrate a voltage difference between a voltage sensed through an (n+1)^{th} RX wire adjacent to the n^{th} RX wire and a first reference voltage different from the second reference voltage. A display device is also disclosed.

### CROSS-REFERENCE TO RELATED APPLICATION

This application claims the benefit of and priority to Korean Patent Application No. 10-2024-0197855, filed Dec. 27, 2024, the entire contents of which are incorporated herein by reference for all purposes.

### BACKGROUND

### 1. Technical Field

The present disclosure relates to a touch sensor driving circuit and a display device including the same.

### 2. Description of Related Art

A driving circuit of a display device reproduces an input image on a pixel array by writing pixel data of the input image to pixels of a display panel. The display device includes a display panel driving circuit such as a data driving circuit that supplies pixel data signals to data lines and a gate driving circuit that supplies gate signals (or scan signals) to gate lines (or scan lines). A flat panel display includes a control circuit that controls the data driving circuit and the gate driving circuit, for example, a timing controller.

A touch screen may be provided on a screen of a display device. In this case, a display panel driving circuit may further include a touch sensor driving circuit that drives touch sensors of the touch screen.

The description of related art should not be considered prior art merely because it is mentioned in or associated with this section. The description of related art includes information that describes one or more aspects of the subject technology, and the description in this section does not limit the scope of the present disclosure.

### SUMMARY

A touch sensor driving circuit is connected to touch wires. The touch wires include TX wires to which a driving signal is applied and RX wires through which a sensing signal of a touch sensor is transmitted. In this case, fringe capacitance occurs on the RX wires that are located closest to the TX wires.

Such a fringe capacitor may cause a touch error, thereby degrading touch performance.

One or more aspects of the present disclosure are directed to solving all the above-described necessity and problems.

One or more aspects of the present disclosure provide a touch sensor driving circuit and a display device including the same.

It should be noted that aspects of the present disclosure are not limited to the above-described aspects, and other aspects of the present disclosure will be apparent to those skilled in the art from the following descriptions.

A touch sensor driving circuit according to embodiments of the present disclosure may include a driving circuit configured to apply a driving signal to first touch electrodes arranged in a display area through a plurality of TX wires; and a sensing circuit configured to sense voltages of second touch electrodes arranged in a first region and a second region within the display area through first RX wires and second RX wires, respectively, the voltages being generated by the driving signal, wherein the sensing circuit is configured to amplify or integrate a voltage difference between a voltage sensed through one n^{th} (where n is a natural number) RX wire positioned closest to TX wires located at opposite outermost sides of the plurality of TX wires and a second reference voltage, and amplify or integrate a voltage difference between a voltage sensed through an (n+1)^{th} RX wire adjacent to the n^{th} RX wire and a first reference voltage different from the second reference voltage.

A touch sensor driving circuit according to embodiments of the present disclosure may include a driving circuit configured to apply a driving signal to first touch electrodes arranged in a display area through a plurality of TX wires; and a sensing circuit configured to sense voltages of second touch electrodes arranged in a first region and a second region within the display area through first RX wires and second RX wires, respectively, the voltages being generated by the driving signal, wherein the sensing circuit is configured to sense a voltage difference between two RX wires respectively positioned closest to TX wires located at opposite outermost sides of the plurality of TX wires.

A display device according to embodiments of the present disclosure may include a display panel in which a plurality of pixels are arranged; a touch panel disposed on the display panel, and including a plurality of first and second touch electrodes arranged in a display area divided into a first region and a second region, a plurality of TX wires connected to the first touch electrodes, and a plurality of RX wires connected to the second touch electrodes; and a touch sensor driver connected to the first and second touch electrodes, wherein the touch sensor driver includes: a driving circuit configured to apply a driving signal to the first touch electrodes through the plurality of TX wires; and a sensing circuit configured to sense, through first RX wires and second RX wires, a voltage of the second touch electrodes arranged in the first region and a voltage of the second touch electrodes arranged in the second region, respectively, the voltages being generated by the driving signal, wherein the sensing circuit is configured to amplify or integrate a voltage difference between a voltage sensed through one n^{th} RX wire positioned closest to TX wires located at opposite outermost sides of the plurality of TX wires and a second reference voltage, and amplify or integrate a voltage difference between a voltage sensed through an (n+1)^{th} RX wire adjacent to the n^{th} RX wire and a first reference voltage different from the second reference voltage.

A display device according to embodiments of the present disclosure may include a display panel in which a plurality of pixels are arranged; a touch panel positioned on the display panel, and including a plurality of first and second touch electrodes arranged in a display area divided into a first region and a second region, a plurality of TX wires connected to the first touch electrodes, and a plurality of RX wires connected to the second touch electrodes; and a touch sensor driver connected to the first and second touch electrodes, wherein the touch sensor driver includes: a driving circuit configured to apply a driving signal to the first touch electrodes through the plurality of TX wires; and a sensing circuit configured to sense, through first RX wires and second RX wires, a voltage of the second touch electrodes arranged in the first region and a voltage of the second touch electrodes arranged in the second region, respectively, the voltages being generated by the driving signal, wherein the sensing circuit is configured to sense a voltage difference between two RX wires respectively positioned closest to TX wires located at opposite outermost sides of the plurality of TX wires.

The present disclosure may prevent touch errors by performing differential sensing between an RX wire closest to the TX wires and another RX wire, and by setting different reference voltages to be applied to the integrator connected to the RX wire closest to the TX wires and the integrator connected to the other RX wire, thereby compensating for a difference in fringe capacitance.

In one or more aspects, since touch errors are prevented, the present disclosure may improve touch performance.

In one or more aspects, since touch errors are prevented, the present disclosure may also enable low-power driving.

The effects of the present specification are not limited to the above-mentioned effects, and other effects that are not mentioned will be apparently understood by those skilled in the art from the following description and the appended claims.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a block diagram illustrating a display device according to an embodiment of the present disclosure;

FIGS. 2 and 3 are diagrams for describing a touch sensor driver shown in FIG. 1;

FIGS. 4 to 6 are diagrams for describing the arrangement relationship of RX wires;

FIG. 7 is a diagram illustrating a configuration of a sensing circuit according to a first embodiment of the present disclosure;

FIG. 8 is a diagram illustrating a modified configuration of the sensing circuit shown in FIG. 7;

FIGS. 9A and 9B are diagrams illustrating a configuration of a sensing circuit according to a second embodiment of the present disclosure;

FIGS. 10A and 10B are diagrams for describing an operating principle of the sensing circuit shown in FIG. 9A;

FIG. 11 is a diagram illustrating a configuration of a sensing circuit according to a third embodiment of the present disclosure;

FIGS. 12 to 14 are diagrams for describing a sensing principle according to a fourth embodiment of the present disclosure; and

FIG. 15 is a diagram illustrating a configuration of a sensing circuit according to the fourth embodiment of the present disclosure.

### DETAILED DESCRIPTION

Advantages and features of the present specification and methods of achieving them will become apparent with reference to preferable embodiments, which are described in detail, in conjunction with the accompanying drawings. However, the present specification is not limited to the embodiments to be described below and may be implemented in different forms, the embodiments are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the embodiments of the present disclosure are only exemplary, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted.

When “including,” “having,” “consisting,” and the like mentioned in the present specification are used, other parts may be added unless “only” is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as “on,” “at an upper portion,” “at a lower portion,” “next to,” and the like, one or more other parts may be located between the two parts unless “immediately” or “directly” is used.

It is understood that, although the terms “first,” “second,” “A,” “B,” “(a),” “(b),” “first-first,” “first-second,” “second-first,” “second-second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In one or more examples a TX wire may refer to a first wire, and an RX wire may refer to a second wire, and vice versa. First RX wires and second RX wires may refer to first-second wires and second-second wires, respectively, and vice versa. A TX wire, a first TX wire, an RX wire, a first RX wire, a second RX wire, a first-second wire, a second-second wires, and the like are merely used to refer to one wire separately from another.

The same reference numerals may refer to substantially the same elements throughout the present disclosure.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

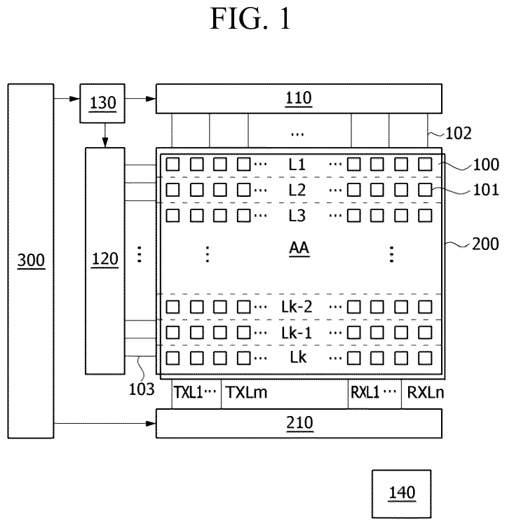

FIG. 1 is a block diagram illustrating a display device according to an embodiment of the present disclosure.

Referring to FIG. 1, a display device according to an embodiment of the present disclosure includes a display panel 100, a display panel driving circuit for writing video data to pixels 101 on the display panel 100, a touch panel 200, a touch sensor driver 210 for driving touch sensors on the touch panel 200, and a power supply 140 for generating power required to drive the pixels 101, the touch sensors, the display panel driving circuit, and the touch sensor driver 210.

A substrate of the display panel 100 may be, but is not limited to, a plastic substrate, a thin glass substrate, or a metal substrate. The display panel 100 may be, but is not limited to, a rectangular shaped panel having a length in the X-axis direction (or first direction), a width in the Y-axis direction (or second direction), and a thickness in the Z-axis direction (or third direction). For example, at least a portion of the display panel 100 may have a curved outer periphery.

The display panel 100 may be implemented as a non-transmissive display panel or a transmissive display panel. The transmissive display panel may be applied to a transparent display device in which an image is displayed on a screen and an actual object is visible beyond the display panel. The display panel 100 may be made as a flexible display panel. The display panel 100 may be made as a stretchable panel that may be stretched.

The display area AA of the display panel 100 includes a pixel array to display an input image. The pixel array includes a plurality of data lines 102, a plurality of gate lines 103 crossing the data lines 102, and pixels arranged in a matrix form. The display panel 100 may further include power lines commonly connected to the pixels. The power lines may be commonly connected to pixel circuits to supply a voltage required for driving pixels 101 to the pixels 101. Power wires may be implemented as long stripes of wires along either the first or second direction, or as mesh wires where the wires in the first direction and the wires in the second direction are electrically connected.

The pixels 101 may include liquid crystal cells having liquid crystal molecules, or light-emitting elements. Each of the pixels 101 may be divided into a red sub-pixel, a green sub-pixel, and a blue sub-pixel for color implementation. Each pixel may further include a white sub-pixel. Each sub-pixel includes a pixel circuit for driving a light emitting element. The light emitting element may include an OLED or an inorganic light emitting diode (LED). Each pixel circuit is connected to the data lines, the gate lines, and the power lines. In the following description, a pixel may be interpreted as a sub-pixel.

The display area AA includes a plurality of pixel lines L1 to Ln. Each of the pixel lines L1 to Ln includes one line of pixels arranged along the line direction (X-axis direction) in the pixel array of the display panel 100. Those pixels arranged in one pixel line share the gate lines 103. The sub-pixels arranged in the column direction Y along the data line direction share the same data line 102. One horizontal period is a time obtained by dividing one frame period by the total number of pixel lines L1 to Ln.

The power supply 140 generates constant voltages (or direct current (DC) voltages) required for driving the pixel array and the display panel driving circuit of the display panel 100 by using a DC-DC converter. The DC-DC converter may include a charge pump, a regulator, a buck converter, a boost converter, and the like. The power supply 140 may adjust the level of the direct-current input voltage applied from a host system 300 to output the constant voltages required to drive the display panel driving circuit and the pixels.

The display panel driving circuit writes pixel data of the input image to the pixels 101 of the display panel 100 under the control of the timing controller 130. The display panel driving circuit includes a data driver 110 and a gate driver 120.

The touch sensors in the touch panel 200 may be disposed as an on-cell type or an add-on type on the display panel 100, or implemented as in-cell type touch sensors embedded in the display panel 100. The touch sensors may be capacitive touch sensors, such as self-capacitance type touch sensors or mutual-capacitance type touch sensors, but are not limited thereto.

The data driver 110 and the touch sensor driver may be integrated into one drive IC or into separate drive ICs. In a mobile terminal or a wearable terminal, components such as the timing controller 130, the power supply 140, the data driver 110, and the touch sensor driving circuit 210 may be integrated into a one drive IC.

The output terminals of the data driver 110 may be electrically connected to the data lines 102 of the display panel 100. The data driver 110 receives video data of an input image provided as a digital signal from a timing controller 130 and outputs a data voltage. The data driver 110 converts the video data of the input image into a gamma compensation voltage using a digital-to-analog converter (hereinafter referred to as a “DAC”), and output the data voltage. A gamma reference voltage may be output from the power source 140. The gamma reference voltage is subdivided into the gamma compensation voltages for each grayscale by a voltage divider circuit in the data driver 110 and provided to the DAC. The DAC generates the data voltage as the gamma compensation voltage corresponding to a grayscale value of the video data. The data voltage from the DAC is output to the data line 102 through an output buffer in each of the data output channels of the data driver 110.

The display panel driving circuit may further include a plurality of de-multiplexers (DEMUX) disposed between the output terminals of the data driver 110 and the data lines 102. If the de-multiplexers are connected between the output terminals of the data driver 110 and the data lines 102, the number of the channels of the data driver 110 may be reduced. The de-multiplexers may be omitted.

The gate driver 120 may be formed on the display panel 100. The gate driver 120 may be disposed in non-display areas NA outside the display area AA in the display panel 100 or at least a part thereof may be disposed within the display area AA.

The gate driver 120 may supply a gate signal to the gate lines 103 in a single feeding method. In the single feeding method, the gate signal is applied to one end of the gate lines 103. In a double feeding method, the gate signal is applied simultaneously to both ends of the gate lines 103.

The gate driver 120 sequentially outputs the gate signal to the gate lines 103 by shifting the pulses of the gate signal using a shift register and/or an edge trigger.

The touch sensor driver 210 is connected to the touch wires. A plurality of touch sensors, that is, first touch electrodes TX and second touch electrodes RX, are connected to the touch wires. The touch wires may be divided into TX wires TXL1 to TXLm, to which driving signals (hereinafter referred to as “TX signals”) are applied to drive the first touch electrodes, and RX wires RXL1 to RXLn, from which output signals of the second touch electrodes are transmitted, but are not limited thereto. The touch sensor driver 210 may convert the voltage of the TX signals through the level shifter and supply it to the TX wires.

The touch sensor driver 210 applies the TX signals to the first touch electrodes through the TX wires TXL1 to TXLm, and amplifies the voltage from the second touch electrodes received from the RX wires RXL1 to RXLn, converts it to digital data, and outputs the touch raw data. The touch sensor driver 210 compares the input touch raw data with a preset reference value and outputs touch data that indicates each of the touch inputs. The touch data exceeding the reference value may be output as a logical value that directs the touch input. The touch data may be transmitted to the host system 300.

The timing controller 130 receives digital video data of an input image and a timing signal synchronized with this data from the host system 300. The timing signal may include a vertical synchronization signal Vsync, a horizontal synchronization signal Hsync, and a data enable signal DE. Since the vertical period and horizontal period may be known by counting the data enable signal DE, the vertical synchronization signal Vsync and the horizontal synchronization signal Hsync may be omitted. The horizontal synchronization signal Hsync and the data enable signal DE have a periodicity of 1 horizontal period (1 H).

The timing controller 130 may control the display panel driving circuit by generating a signal for controlling the operation timing of the display panel driving circuit based on the timing signals Vsync, Hsync, DE received from the host system 300.

The host system 300 may scale an image signal from a video source according to the resolution of the display panel 100, and may transmit it to the timing controller 130 together with the timing signals. The host system 300 may process user commands received by means of touch input in response to touch data TDATA input from the touch sensor driver 210.

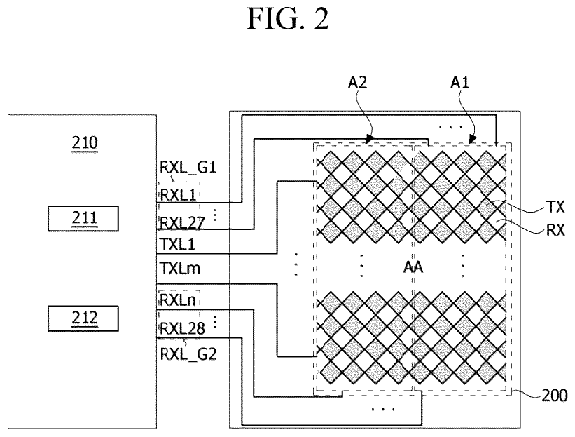

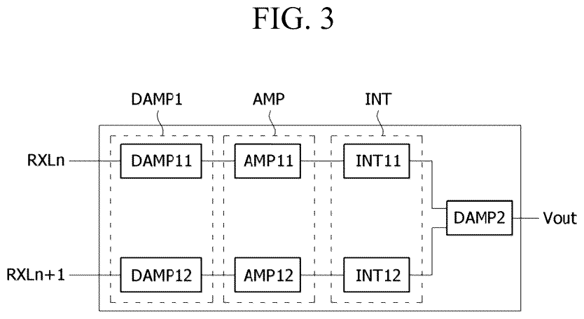

FIGS. 2 and 3 are diagrams for describing a touch sensor driver shown in FIG. 1 and FIGS. 4 to 6 are diagrams for describing the arrangement relationship of RX wires.

Referring to FIG. 2, the touch sensors, i.e., a first touch electrode TX and a second touch electrode RX, of the touch panel may be formed in different layers. For example, the first touch electrode TX may be arranged in a first layer positioned on an upper portion of the display panel, and the second touch electrode RX may be arranged in a second layer positioned above the first layer. However, the present disclosure is not necessarily limited thereto.

The first touch electrode TX and the second touch electrode RX may be formed by patterning a metal layer having conductivity and may be formed in a mesh shape. The first touch electrode TX and the second touch electrode RX may be formed of, for example, a transparent material such as indium tin oxide (ITO).

Based on the TX wires TXL to which the TX signal or the driving signal is applied, the RX wires may be classified into first group RX wires RXL_G1 and second group RX wires RXL_G2. The first group RX wires RXL_G1 may be connected to the second touch electrodes RX arranged in a first region A1, and the second group RX wires RXL_G2 may be connected to the second touch electrodes RX arranged in a second region A2.

The touch sensor driver 210 may apply a driving signal to the first touch electrode TX through the TX wires TXL, and may sense the voltages of the second touch electrodes through the first RX wires and the second RX wires.

The touch sensor driver 210 may include a driving circuit 211 and a sensing circuit 212. The driving circuit 211 may sequentially apply a driving signal to the first touch electrodes TX through the TX wires TXL.

The sensing circuit 212 may sense touch signals from the second touch electrodes RX received through the RX wires RXL. The sensing circuit 212 may include a first differential amplifier DAMP1, an amplifier AMP, an integrator INT, and a second differential amplifier DAMP2.

The first differential amplifier DAMP1 may include a first-first differential amplifier DAMP11 connected to an n^{th} RX wire RXLn and a first-second differential amplifier DAMP12 connected to an (n+1)^{th} RX wire RXLn+1. The first-first differential amplifier DAMP11 may amplify and output a difference between a voltage of the n^{th} RX wire RXLn and a predetermined reference voltage. The first-second differential amplifier DAMP12 may amplify and output a difference between a voltage of the (n+1)^{th} RX wire RXLn+1 and a predetermined reference voltage. In one or more examples, n may be a natural number.

The amplifier AMP may include a first-first amplifier AMP11 and a first-second amplifier AMP12. The first-first amplifier AMP11 may amplify and output a signal outputted from the first-first differential amplifier DAMP11. The first-second amplifier AMP12 may amplify and output a signal outputted from the first-second differential amplifier DAMP12.

The integrator INT may include a first-first integrator INT11 and a first-second integrator INT12. The first-first integrator INT11 may integrate and output a signal amplified by the first-first amplifier AMP11. The first-second integrator INT12 may integrate and output a signal amplified by the first-second amplifier AMP12.

The second differential amplifier DAMP2 may amplify and output a difference between a signal outputted from the first-first integrator INT11 and a signal outputted from the first-second integrator INT12.

As the second differential amplifier DAMP2 amplifies and outputs a difference between a voltage of the n^{th} RX wire RXLn and a voltage of the (n+1)^{th} RX wire RXLn+1, differential sensing is performed.

The touch sensor driver 210 may further include a recognition circuit. The recognition circuit may compare touch data received from the sensing circuit 212 with a preset threshold value, detect touch data higher than the threshold value, and generate coordinates of each touch input. The recognition circuit may transmit the generated coordinates of the touch input to the host system 300.

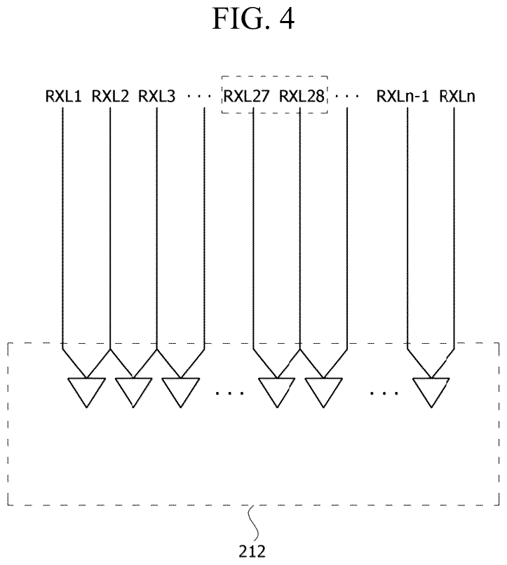

In this case, the RX wires RXL1 to RXLn may be connected to the sensing circuit 212 as shown in FIG. 4. Accordingly, the sensing circuit 212 may perform differential sensing between the two adjacent RX wires.

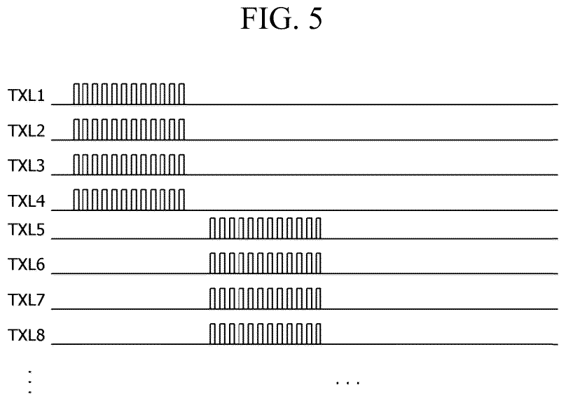

Accordingly, in the driving circuit 211, TX signals may be applied in units of four TX wires TXL, as shown in FIG. 5. For example, TX signals may be simultaneously applied to the first to fourth TX wires TXL1 to TXL4, and then to the fifth to eighth TX wires TXL5 to TXL8.

However, as shown in FIG. 2, a twenty-seventh RX wire RXL27 is arranged adjacent to the first TX wire TXL1, and the n^{th} RX wire RXLn is arranged adjacent to the m^{th} TX wire TXLm. Accordingly, fringe capacitance increases in the twenty-seventh RX wire RXL27 and the n^{th} RX wire RXLn due to the adjacent first TX wire TXL1 and m^{th} TX wire TXLm.

That is, when the first to n^{th} RX wires RXL1 to RXLn are sequentially connected as shown in FIG. 4, differential sensing is performed between the twenty-seventh RX wire RXL27, which exhibits relatively large fringe capacitance, and a twenty-eighth RX wire RXL28, which exhibits relatively small fringe capacitance.

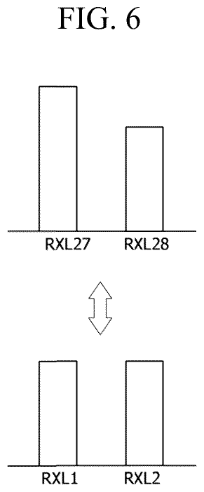

As shown in FIG. 6, a result of differential sensing between the twenty-seventh RX wire RXL27 and the twenty-eighth RX wire RXL28, where fringe capacitance occurs, differs from a result of differential sensing between the first RX wire RXL1 and the second RX wire RXL2, thereby degrading touch performance.

Accordingly, differential sensing in consideration of such fringe capacitance should be performed. To this end, in a first embodiment, a reference voltage applied to the integrator in the sensing circuit is adjusted.

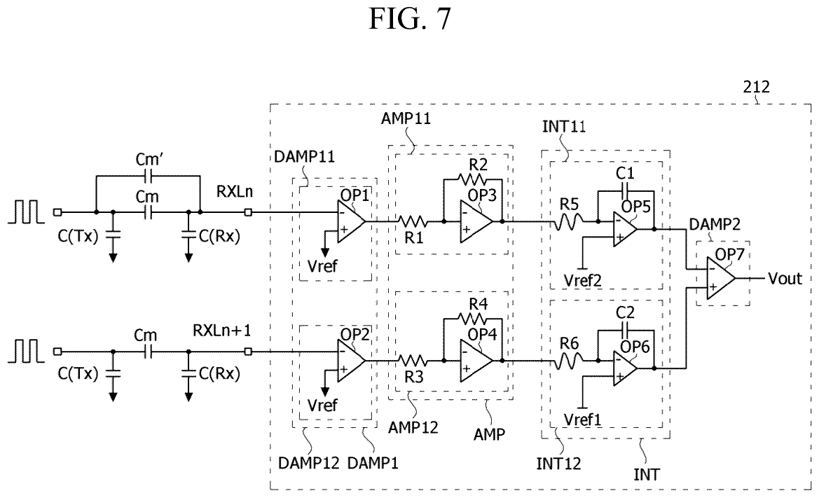

FIG. 7 is a diagram illustrating a configuration of a sensing circuit according to a first embodiment of the present disclosure.

Referring to FIG. 7, the sensing circuit 212 according to the first embodiment of the present disclosure may differentially sense touch signals from the second touch electrodes RX received through the adjacent RX wires RXL. The sensing circuit 212 may include the first differential amplifier DAMP1, the amplifier AMP, the integrator INT, and the second differential amplifier DAMP2.

The first differential amplifier DAMP1 may include the first-first differential amplifier DAMP11 connected to the n^{th} RX wire RXLn and the first-second differential amplifier DAMP12 connected to the (n+1)^{th} RX wire RXLn+1.

The first-first differential amplifier DAMP11 may amplify and output a difference between a voltage of the n^{th} RX wire RXLn and a predetermined reference voltage Vref. The first-first differential amplifier DAMP11 may include a first operational amplifier OP1. The inverting input terminal (−) of the first operational amplifier OP1 may be connected to the n^{th} RX wire RXLn, and the non-inverting input terminal (+) thereof may be connected to a power line to which the reference voltage Vref is applied.

Here, Cm represents the fringe capacitance between the first touch electrode TX and the second touch electrode RX in the display area, and Cm′ represents the fringe capacitance between the TX wire and the RX wire.

The first-second differential amplifier DAMP12 may amplify and output a difference between a voltage of the (n+1)^{th} RX wire RXLn+1 and the predetermined reference voltage Vref. The first-second differential amplifier DAMP12 may include a second operational amplifier OP2. The inverting input terminal (−) of the second operational amplifier OP2 may be connected to the (n+1)^{th} RX wire RXLn+1, and the non-inverting input terminal (+) thereof may be connected to a power line to which the reference voltage Vref is applied.

The amplifier AMP may include the first-first amplifier AMP11 and the first-second amplifier AMP12.

The first-first amplifier AMP11 may amplify and output a signal outputted from the first-first differential amplifier DAMP11. The first-first amplifier AMP11 may include a third operational amplifier OP3, a first resistor R1, and a second resistor R2. The first resistor R1 may be connected to the input terminal of the third operational amplifier OP3, and the second resistor R2 may be connected between the input terminal and the output terminal of the third operational amplifier OP3.

The first-second amplifier AMP12 may amplify and output a signal outputted from the first-second differential amplifier DAMP12. The first-second amplifier AMP12 may include a fourth operational amplifier OP4, a third resistor R3, and a fourth resistor R4. The third resistor R3 may be connected to the input terminal of the fourth operational amplifier OP4, and the fourth resistor R4 may be connected between the input terminal and the output terminal of the fourth operational amplifier OP4.

The integrator INT may include the first-first integrator INT11 and the first-second integrator INT12.

The first-first integrator INT11 may integrate and output a signal amplified by the first-first amplifier AMP11 using a predetermined second reference voltage Vref2. The first-first integrator INT11 may include a fifth operational amplifier OP5, a fifth resistor R5, and a first capacitor C1. The fifth resistor R5 may be connected to the inverting input terminal of the fifth operational amplifier OP5, and the first capacitor C1 may be connected between the inverting input terminal and the output terminal of the fifth operational amplifier OP5.

The first-second integrator INT12 may integrate and output a signal amplified by the first-second amplifier AMP12 using a predetermined first reference voltage Vref1. The first-second integrator INT12 may include a sixth operational amplifier OP6, a sixth resistor R6, and a second capacitor C2. The sixth resistor R6 may be connected to the inverting input terminal of the sixth operational amplifier OP6, and the second capacitor C2 may be connected between the inverting input terminal and the output terminal of the sixth operational amplifier OP6.

In this case, the second reference voltage Vref2 applied to the first-first integrator INT11, which integrates a signal received from the n^{th} RX wire RXLn where fringe capacitance occurs, may be set to be greater than the first reference voltage Vref1 applied to the first-second integrator INT12, which integrates a signal received from the (n+1)^{th} RX wire RXL(n+1) where fringe capacitance does not occur.

In an embodiment, the first reference voltage Vref1 may be the same as the reference voltage Vref.

In contrast, when fringe capacitance does not occur or occurs to a negligible degree in both the n^{th} RX wire RXLn and the (n+1)^{th} RX wire RXLn+1, the reference voltages applied to the first-first integrator INT11 and the first-second integrator INT12 may be set to the same voltage.

The second differential amplifier DAMP2 may amplify and output a difference between a signal outputted from the first-first integrator INT11 and a signal outputted from the first-second integrator INT12. The second differential amplifier DAMP2 may include a seventh operational amplifier OP7. The inverting input terminal (−) of the seventh operational amplifier OP7 may be connected to the output terminal of the first-first integrator INT11, and the non-inverting input terminal (+) thereof may be connected to the output terminal of the first-second integrator INT12.

Differential sensing may be performed by amplifying and outputting a difference between a voltage of the n^{th} RX wire RXLn and a voltage of the (n+1)^{th} RX wire RXLn+1 in the second differential amplifier DAMP2.

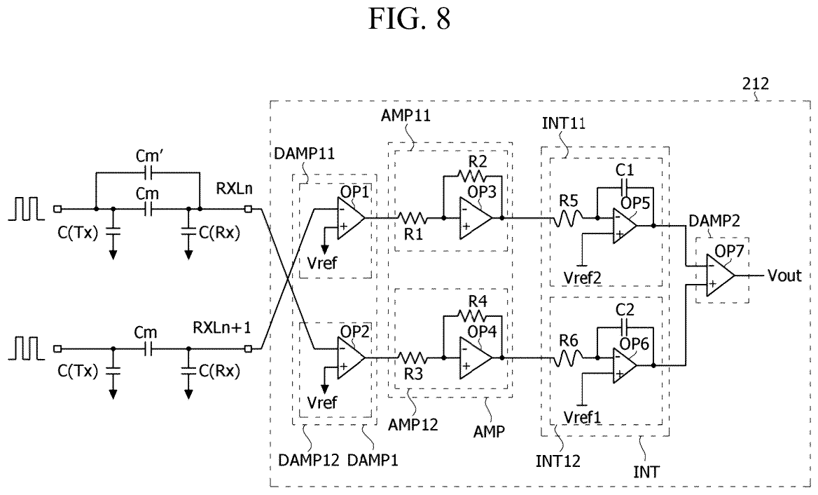

FIG. 8 is a diagram illustrating a modified configuration of the sensing circuit shown in FIG. 7.

Referring to FIG. 8, a modified sensing circuit 212 of the present disclosure may include the first differential amplifier DAMP1, the amplifier AMP, the integrator INT, and the second differential amplifier DAMP2.

The first differential amplifier DAMP1 may include the first-first differential amplifier DAMP11 connected to the (n+1)^{th} RX wire RXLn+1 and the first-second differential amplifier DAMP12 connected to the n^{th} RX wire RXLn.

The first-first differential amplifier DAMP11 may amplify and output a difference between a voltage of the (n+1)^{th} RX wire RXLn+1 and the predetermined reference voltage Vref. The first-first differential amplifier DAMP11 may include the first operational amplifier OP1. The inverting input terminal (−) of the first operational amplifier OP1 may be connected to the (n+1)^{th} RX wire RXLn+1, and the non-inverting input terminal (+) thereof may be connected to a power line to which the reference voltage Vref is applied.

The first-second differential amplifier DAMP12 may amplify and output a difference between a voltage of the n^{th} RX wire RXLn and the predetermined reference voltage Vref. The first-second differential amplifier DAMP12 may include the second operational amplifier OP2. The inverting input terminal (−) of the second operational amplifier OP2 may be connected to the n^{th} RX wire RXLn, and the non-inverting input terminal (+) thereof may be connected to a power line to which the reference voltage Vref is applied.

The amplifier AMP may include the first-first amplifier AMP11 and the first-second amplifier AMP12.

The first-first amplifier AMP11 may amplify and output a signal outputted from the first-first differential amplifier DAMP11. The first-first amplifier AMP11 may include the third operational amplifier OP3, the first resistor R1, and the second resistor R2. The first resistor R1 may be connected to the input terminal of the third operational amplifier OP3, and the second resistor R2 may be connected between the input terminal and the output terminal of the third operational amplifier OP3.

The first-second amplifier AMP12 may amplify and output a signal outputted from the first-second differential amplifier DAMP12. The first-second amplifier AMP12 may include the fourth operational amplifier OP4, the third resistor R3, and the fourth resistor R4. The third resistor R3 may be connected to the input terminal of the fourth operational amplifier OP4, and the fourth resistor R4 may be connected between the input terminal and the output terminal of the fourth operational amplifier OP4.

The integrator INT may include the first-first integrator INT11 and the first-second integrator INT12.

The first-first integrator INT11 may integrate and output a signal amplified by the first-first amplifier AMP11 using the predetermined second reference voltage Vref2. The first-first integrator INT11 may include the fifth operational amplifier OP5, the fifth resistor R5, and the first capacitor C1. The fifth resistor R5 may be connected to the inverting input terminal of the fifth operational amplifier OP5, and the first capacitor C1 may be connected between the inverting input terminal and the output terminal of the fifth operational amplifier OP5.

The first-second integrator INT12 may integrate and output a signal amplified by the first-second amplifier AMP12 using the predetermined first reference voltage Vref1. The first-second integrator INT12 may include the sixth operational amplifier OP6, the sixth resistor R6, and the second capacitor C2. The sixth resistor R6 may be connected to the inverting input terminal of the sixth operational amplifier OP6, and the second capacitor C2 may be connected between the inverting input terminal and the output terminal of the sixth operational amplifier OP6.

In this case, the first reference voltage Vref1 applied to the first-second integrator INT12, which integrates a signal received from the n^{th} RX wire RXLn where fringe capacitance occurs, may be set greater than the second reference voltage Vref2 applied to the first-first integrator INT11, which integrates a signal received from the (n+1)^{th} RX wire RXLn+1 where fringe capacitance does not occur.

This is because, unlike the sensing circuit of FIG. 7, the signal received from the n^{th} RX wire RXLn is inputted to the non-inverting input terminal of the seventh operational amplifier OP7, and the signal received from the (n+1)^{th} RX wire RXLn+1 is inputted to the inverting input terminal of the seventh operational amplifier OP7.

The second differential amplifier DAMP2 may amplify and output a difference between a signal outputted from the first-first integrator INT11 and a signal outputted from the first-second integrator INT12. The second differential amplifier DAMP2 may include the seventh operational amplifier OP7. The inverting input terminal (−) of the seventh operational amplifier OP7 may be connected to the output terminal of the first-first integrator INT11, and the non-inverting input terminal (+) thereof may be connected to the output terminal of the first-second integrator INT12.

Differential sensing may be performed by amplifying and outputting a difference between a voltage of the n^{th} RX wire RXLn and a voltage of the (n+1)^{th} RX wire RXLn+1 in the second differential amplifier DAMP2.

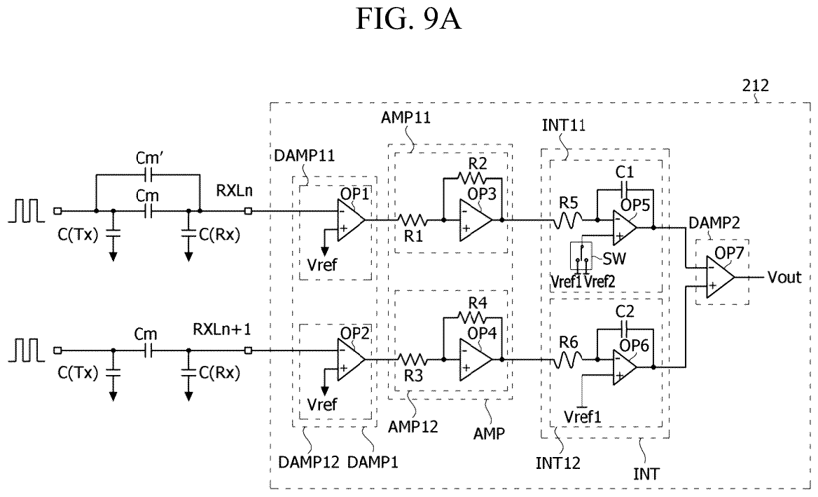

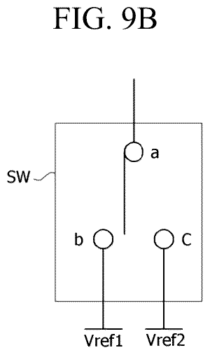

FIGS. 9A and 9B are diagrams illustrating a configuration of a sensing circuit according to a second embodiment of the present disclosure.

Referring to FIG. 9A, a sensing circuit 212 according to a second embodiment of the present disclosure may differentially sense touch signals from the second touch electrodes RX received through the adjacent RX wires RXL. The sensing circuit 212 may include the first differential amplifier DAMP1, the amplifier AMP, the integrator INT, and the second differential amplifier DAMP2.

The first differential amplifier DAMP1 may include the first-first differential amplifier DAMP11 connected to the n^{th} RX wire RXLn and the first-second differential amplifier DAMP12 connected to the (n+1)^{th} RX wire RXLn+1.

The first-first differential amplifier DAMP11 may amplify and output a difference between a voltage of the n^{th} RX wire RXLn and the predetermined reference voltage Vref. The first-first differential amplifier DAMP11 may include the first operational amplifier OP1. The inverting input terminal (−) of the first operational amplifier OP1 may be connected to the n^{th} RX wire RXLn, and the non-inverting input terminal (+) thereof may be connected to a power line to which the reference voltage Vref is applied.

The first-second differential amplifier DAMP12 may amplify and output a difference between a voltage of the (n+1)^{th} RX wire RXLn+1 and the predetermined reference voltage Vref. The first-second differential amplifier DAMP12 may include the second operational amplifier OP2. The inverting input terminal (−) of the second operational amplifier OP2 may be connected to the (n+1)^{th} RX wire RXLn+1, and the non-inverting input terminal (+) thereof may be connected to a power line to which the reference voltage Vref is applied.

The amplifier AMP may include the first-first amplifier AMP11 and the first-second amplifier AMP12.

The first-first amplifier AMP11 may amplify and output a signal outputted from the first-first differential amplifier DAMP11. The first-first amplifier AMP11 may include the third operational amplifier OP3, the first resistor R1, and the second resistor R2. The first resistor R1 may be connected to the input terminal of the third operational amplifier OP3, and the second resistor R2 may be connected between the input terminal and the output terminal of the third operational amplifier OP3.

The first-second amplifier AMP12 may amplify and output a signal outputted from the first-second differential amplifier DAMP12. The first-second amplifier AMP12 may include the fourth operational amplifier OP4, the third resistor R3, and the fourth resistor R4. The third resistor R3 may be connected to the input terminal of the fourth operational amplifier OP4, and the fourth resistor R4 may be connected between the input terminal and the output terminal of the fourth operational amplifier OP4.

The integrator INT may include the first-first integrator INT11 and the first-second integrator INT12.

The first-first integrator INT11 may integrate and output a signal amplified by the first-first amplifier AMP11 using the first reference voltage Vref1 or the second reference voltage Vref2. The first-first integrator INT11 may include the fifth operational amplifier OP5, the fifth resistor R5, the first capacitor C1, and a switch SW. The fifth resistor R5 may be connected to the inverting input terminal of the fifth operational amplifier OP5, and the first capacitor C1 may be connected between the inverting input terminal and the output terminal of the fifth operational amplifier OP5.

As shown in FIG. 9B, the switch SW may be driven by a control signal generated from the driving circuit such that a first contact point “a” is connected to a second contact point “b” to apply the first reference voltage Vref1, or the first contact point “a” is connected to a third contact point “c” to apply the second reference voltage Vref2. Here, the switch SW may be implemented as a three-way switch, but the present disclosure is not limited thereto.

That is, the integrator connected to the RX wire where the fringe capacitance Cm′ occurs may be configured to selectively apply the first reference voltage or the second reference voltage. This is because the distance between the TX wire to which the driving signal is applied and the RX wire closest to the TX wire is designed to be equal to or greater than a threshold value, so that the fringe capacitance Cm′ caused by the distance between the TX and RX wires occurs only to a negligible extent.

The first-second integrator INT12 may integrate and output a signal amplified by the first-second amplifier AMP12 using the first reference voltage Vref1. The first-second integrator INT12 may include the sixth operational amplifier OP6, the sixth resistor R6, and the second capacitor C2. The sixth resistor R6 may be connected to the inverting input terminal of the sixth operational amplifier OP6, and the second capacitor C2 may be connected between the inverting input terminal and the output terminal of the sixth operational amplifier OP6.

The second differential amplifier DAMP2 may amplify and output a difference between a signal outputted from the first-first integrator INT11 and a signal outputted from the first-second integrator INT12. The second differential amplifier DAMP2 may include the seventh operational amplifier OP7. The inverting input terminal (−) of the seventh operational amplifier OP7 may be connected to the output terminal of the first-first integrator INT11, and the non-inverting input terminal (+) thereof may be connected to the output terminal of the first-second integrator INT12.

Differential sensing is performed by amplifying and outputting a difference between a voltage of the n^{th} RX wire RXLn and a voltage of the (n+1)^{th} RX wire RXLn+1 in the second differential amplifier DAMP2.

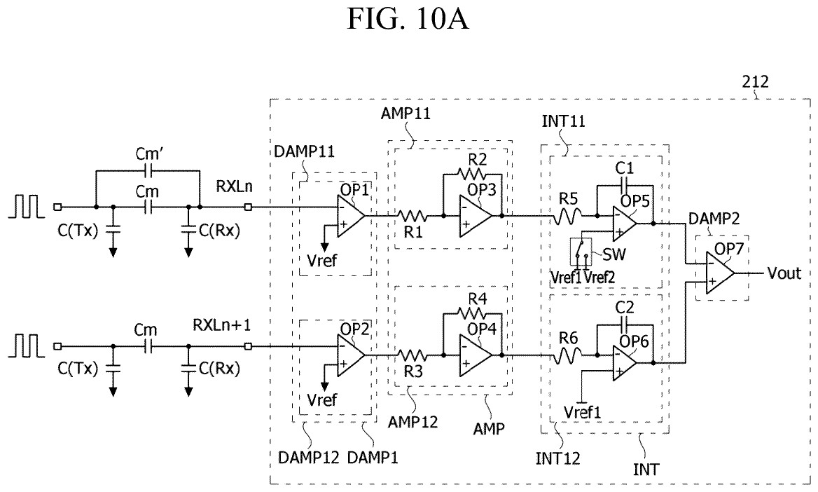

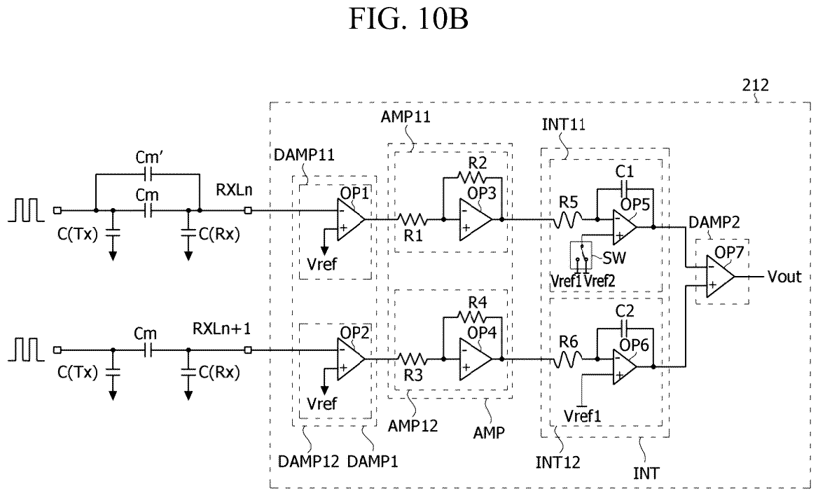

FIGS. 10A and 10B are diagrams for describing an operating principle of the sensing circuit shown in FIG. 9A.

Referring to FIG. 10A, when the fringe capacitance on the n^{th} RX wire RXLn is less than a threshold value or is absent, the first reference voltage Vref1 is applied to the non-inverting input terminal (+) of the first-first integrator INT11.

Referring to FIG. 10B, when the fringe capacitance on the n^{th} RX wire RXLn is present and is equal to or greater than the threshold value, the second reference voltage Vref2 is applied to the non-inverting input terminal (+) of the first-first integrator INT11.

In a third embodiment of the present disclosure, instead of applying different reference voltages to the integrators in the sensing circuit, different reference voltages are intended to be applied to the differential amplifiers.

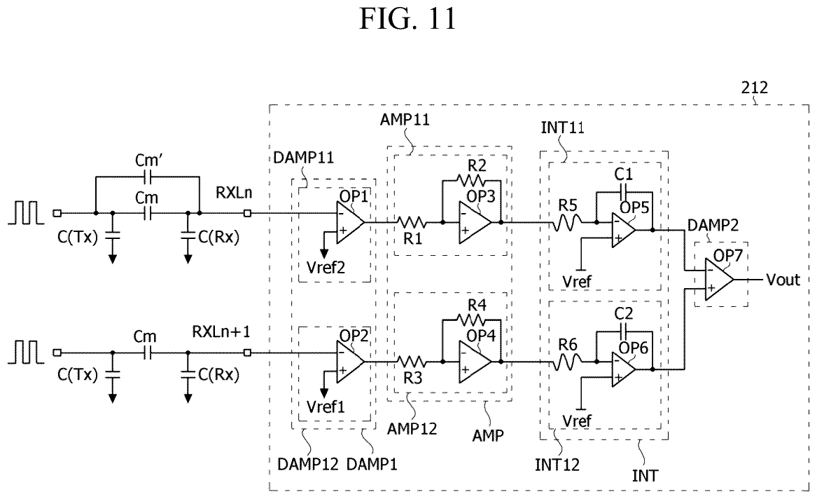

FIG. 11 is a diagram illustrating a configuration of a sensing circuit according to a third embodiment of the present disclosure.

Referring to FIG. 11, the sensing circuit 212 according to the third embodiment of the present disclosure may differentially sense touch signals from the second touch electrodes RX received through adjacent RX wires RXL. The sensing circuit 212 may include the first differential amplifier DAMP1, the amplifier AMP, the integrator INT, and the second differential amplifier DAMP2.

The sensing circuit according to the third embodiment has the same configuration and function as the sensing circuit of the first embodiment shown in FIG. 7, and only the reference voltages applied to the first differential amplifier DAMP1 and the integrator INT are different. Thus, only the first differential amplifier DAMP1 and the integrator INT will be described.

The first differential amplifier DAMP1 may include the first-first differential amplifier DAMP11 connected to the n^{th} RX wire RXLn and the first-second differential amplifier DAMP12 connected to the (n+1)^{th} RX wire RXLn+1.

The first-first differential amplifier DAMP11 may amplify and output a difference between a voltage of the n^{th} RX wire RXLn and the predetermined second reference voltage Vref2. The first-first differential amplifier DAMP11 may include the first operational amplifier OP1. The inverting input terminal (−) of the first operational amplifier OP1 may be connected to the n^{th} RX wire RXLn, and the non-inverting input terminal (+) thereof may be connected to a power line to which the second reference voltage Vref2 is applied.

The first-second differential amplifier DAMP12 may amplify and output a difference between a voltage of the (n+1)^{th} RX wire RXLn+1 and the predetermined first reference voltage Vref1. The first-second differential amplifier DAMP12 may include the second operational amplifier OP2. The inverting input terminal (−) of the second operational amplifier OP2 may be connected to the (n+1)^{th} RX wire RXLn+1, and the non-inverting input terminal (+) thereof may be connected to a power line to which the first reference voltage Vref1 is applied.

The amplifier AMP may include the first-first amplifier AMP11 and the first-second amplifier AMP12.

The first-first amplifier AMP11 may amplify and output a signal outputted from the first-first differential amplifier DAMP11. The first-first amplifier AMP11 may include the third operational amplifier OP3, the first resistor R1, and the second resistor R2. The first resistor R1 may be connected to the input terminal of the third operational amplifier OP3, and the second resistor R2 may be connected between the input terminal and the output terminal of the third operational amplifier OP3.

The first-second amplifier AMP12 may amplify and output a signal outputted from the first-second differential amplifier DAMP12. The first-second amplifier AMP12 may include the fourth operational amplifier OP4, the third resistor R3, and the fourth resistor R4. The third resistor R3 may be connected to the input terminal of the fourth operational amplifier OP4, and the fourth resistor R4 may be connected between the input terminal and the output terminal of the fourth operational amplifier OP4.

The integrator INT may include the first-first integrator INT11 and the first-second integrator INT12.

The first-first integrator INT11 may integrate and output a signal amplified by the first-first amplifier AMP11 using the predetermined reference voltage Vref. The first-first integrator INT11 may include the fifth operational amplifier OP5, the fifth resistor R5, and the first capacitor C1. The fifth resistor R5 may be connected to the inverting input terminal of the fifth operational amplifier OP5, and the first capacitor C1 may be connected between the inverting input terminal and the output terminal of the fifth operational amplifier OP5.

The first-second integrator INT12 may integrate and output a signal amplified by the first-second amplifier AMP12 using the predetermined reference voltage Vref. The first-second integrator INT12 may include the sixth operational amplifier OP6, the sixth resistor R6, and the second capacitor C2. The sixth resistor R6 may be connected to the inverting input terminal of the sixth operational amplifier OP6, and the second capacitor C2 may be connected between the inverting input terminal and the output terminal of the sixth operational amplifier OP6.

The second differential amplifier DAMP2 may amplify and output a difference between a signal outputted from the first-first integrator INT11 and a signal outputted from the first-second integrator INT12. The second differential amplifier DAMP2 may include the seventh operational amplifier OP7. The inverting input terminal (−) of the seventh operational amplifier OP7 may be connected to the output terminal of the first-first integrator INT11, and the non-inverting input terminal (+) thereof may be connected to the output terminal of the first-second integrator INT12.

Differential sensing may be performed by amplifying and outputting a difference between a voltage of the n^{th} RX wire RXLn and a voltage of the (n+1)^{th} RX wire RXLn+1 in the second differential amplifier DAMP2.

In a fourth embodiment of the present disclosure, instead of applying different reference voltages to the integrators or the differential amplifiers in the sensing circuit, the arrangement positions of the RX wires connected to the sensing circuit are changed.

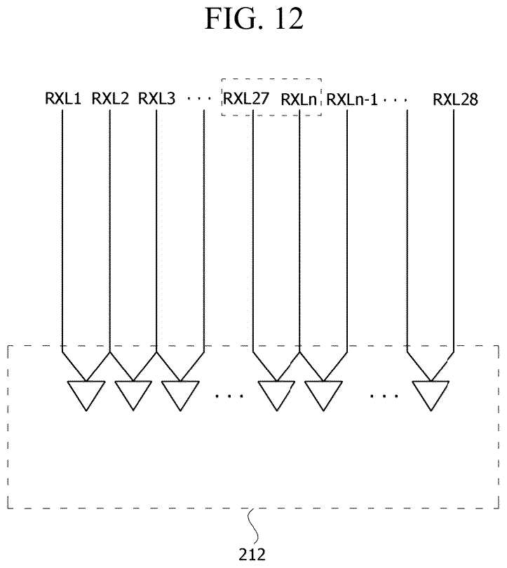

FIGS. 12 to 14 are diagrams for describing a sensing principle according to a fourth embodiment of the present disclosure.

Referring to FIG. 12, in the fourth embodiment of the present disclosure, among the RX wires RXL1 to RXLn, the RX wires that exhibit relatively large fringe capacitance are arranged to be adjacent to each other in the sensing circuit 212.

For example, the twenty-seventh RX wire RXL27 and the n^{th} RX wire RXLn are adjacently connected to the sensing circuit 212. The first to twenty-seventh RX wires RXL1 to RXL27 are adjacently connected in sequential order, and the n^{th} to twenty-eighth RX wires RXLn to RXL28 are adjacently connected in reverse order.

Accordingly, in the sensing circuit 212 according to an embodiment, differential sensing is performed between the twenty-seventh RX wire RXL27 and the n^{th} RX wire RXLn, which exhibit relatively large fringe capacitance.

To achieve this, TX signals need to be applied such that the influence of the drive signal applied to the TX wires equally affects the first to twenty-seventh RX wires and the n^{th} to twenty-eighth RX wires.

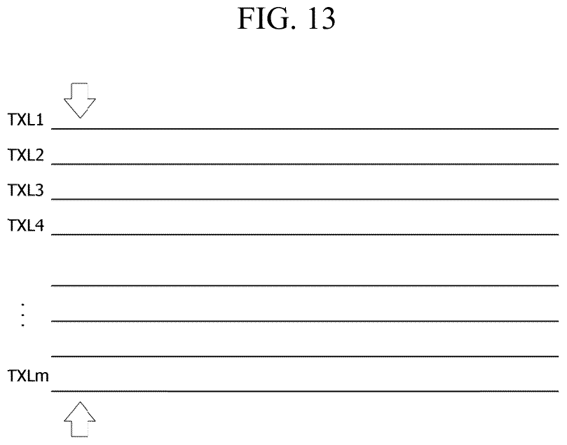

In addition, since the n^{th} to twenty-eighth RX wires RXLn to RXL28 are adjacently connected in reverse order and differential sensing is performed between the twenty-seventh RX wire RXL27 and the n^{th} RX wire RXLn, TX signals need to be simultaneously applied from a region of the TX wires corresponding to the outermost region of the first to twenty-seventh RX wires RXL1 to RXL27 and the n^{th} to twenty-eighth RX wires RXLn to RXL28 toward the central region of the TX wires, as shown in FIG. 13.

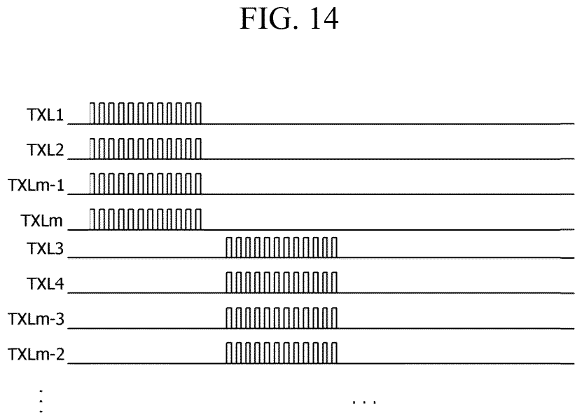

Accordingly, in an embodiment, as shown in FIG. 14, TX signals are applied in units of four TX wires, and TX signals are simultaneously applied to the first and second TX wires TXL1 and TXL2 and the (m−1)^{th} and m^{th} TX wires TXLm−1 and TXLm, and then simultaneously applied to the third and fourth TX wires TXL3 and TXL4 and the (m−3)^{th} and (m−2)^{th} TX wires TXLm−3 and TXLm−2.

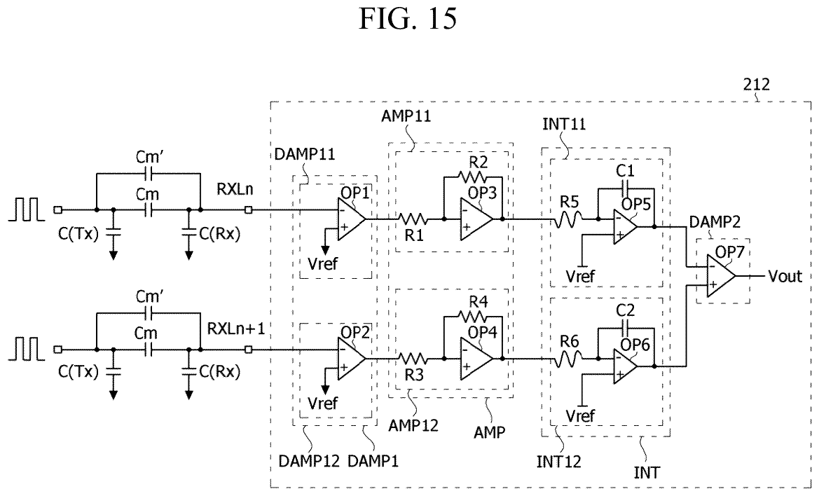

FIG. 15 is a diagram illustrating a configuration of a sensing circuit according to the fourth embodiment of the present disclosure.

Referring to FIG. 15, the sensing circuit 212 according to the fourth embodiment of the present disclosure may differentially sense touch signals from the second touch electrodes RX received through the adjacent RX wires RXL. The sensing circuit 212 may include the first differential amplifier DAMP1, the amplifier AMP, the integrator INT, and the second differential amplifier DAMP2.

The sensing circuit according to the fourth embodiment has the same configuration and function as the sensing circuit of the first embodiment. However, only the reference voltage applied to the integrator differs, and therefore, only this aspect will be described.

The integrator INT may include the first-first integrator INT11 and the first-second integrator INT12.

The first-first integrator INT11 may integrate and output a signal amplified by the first-first amplifier AMP11. The first-first integrator INT11 may include the fifth operational amplifier OP5, the fifth resistor R5, and the first capacitor C1. The fifth resistor R5 is connected to the inverting input terminal (−) of the fifth operational amplifier OP5, and a power line to which the reference voltage Vref is applied is connected to the non-inverting input terminal (+) of the fifth operational amplifier OP5. The first capacitor C1 may be connected between the inverting input terminal (−) and the output terminal of the fifth operational amplifier OP5.

The first-second integrator INT12 may integrate and output a signal amplified by the first-second amplifier AMP12. The first-second integrator INT12 may include the sixth operational amplifier OP6, the sixth resistor R6, and the second capacitor C2. The sixth resistor R6 may be connected to the inverting input terminal (−) of the sixth operational amplifier OP6, and a power line to which the reference voltage Vref is applied is connected to the non-inverting input terminal (+) of the sixth operational amplifier OP5. The second capacitor C2 may be connected between the inverting input terminal (−) and the output terminal of the sixth operational amplifier OP6.

In the fourth embodiment, differential sensing is performed between the RX wires where the fringe capacitance Cm′ occurs, and also between the RX wires where the fringe capacitance Cm′ is so small as to be negligible. Therefore, it is not necessary to apply different reference voltages to the integrators.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A touch sensor driving circuit, comprising:
a driving circuit configured to apply a driving signal to first touch electrodes arranged in a display area through a plurality of TX wires; and
a sensing circuit configured to sense voltages of second touch electrodes arranged in a first region and a second region within the display area through first RX wires and second RX wires, respectively, the voltages being generated by the driving signal,
wherein the sensing circuit is configured to amplify or integrate a voltage difference between a voltage sensed through one n^{th} RX wire positioned closest to TX wires located at opposite outermost sides of the plurality of TX wires and a second reference voltage, and amplify or integrate a voltage difference between a voltage sensed through an (n+1)^{th} RX wire adjacent to the n^{th} RX wire and a first reference voltage different from the second reference voltage, where n is a natural number.

2. The touch sensor driving circuit of claim 1, wherein the sensing circuit includes:
a first-first differential amplifier configured to amplify and output a difference between a voltage of the second touch electrode sensed through the n^{th} RX wire and the first reference voltage;
a first-second differential amplifier configured to amplify and output a difference between a voltage of the second touch electrode sensed through the (n+1)^{th} RX wire and the first reference voltage;
a first-first amplifier configured to amplify and output a signal outputted from the first-first differential amplifier;
a first-second amplifier configured to amplify and output a signal outputted from the first-second differential amplifier;
a first-first integrator configured to integrate and output a difference between a signal amplified by the first-first amplifier and the second reference voltage higher than the first reference voltage;
a first-second integrator configured to integrate and output a difference between a signal amplified by the first-second amplifier and the first reference voltage; and
a second differential amplifier configured to amplify and output a difference between a signal outputted from the first-first integrator and a signal outputted from the first-second integrator, and
wherein the second touch electrode is among the second touch electrodes.

3. The touch sensor driving circuit of claim 2, wherein the first-first integrator includes an operational amplifier, a resistor, and a capacitor,
wherein the operational amplifier includes an inverting input terminal connected to the resistor and a non-inverting input terminal connected to a power line to which the second reference voltage is applied,
wherein the resistor is connected between the n^{th} RX wire and the inverting input terminal of the operational amplifier, and
wherein the capacitor is connected to the inverting input terminal of the operational amplifier.

4. The touch sensor driving circuit of claim 3, wherein the first-first integrator further includes a first switch and a second switch,
wherein the first switch is connected between the non-inverting input terminal of the operational amplifier and a power line to which the first reference voltage is applied, and
wherein the second switch is connected between the non-inverting input terminal of the operational amplifier and the power line to which the second reference voltage is applied.

5. The touch sensor driving circuit of claim 4, wherein each of the first and second switches includes a first contact point connected to the non-inverting input terminal of the operational amplifier, a second contact point connected to the power line to which the first reference voltage is applied, and a third contact point connected to the power line to which the second reference voltage is applied.

6. The touch sensor driving circuit of claim 5, wherein the driving circuit is configured to connect the first contact point to the second contact point when a magnitude of fringe capacitance generated in an RX wire is smaller than a predetermined threshold value, and connect the first contact point to the third contact point when the magnitude of the fringe capacitance generated in the RX wire is equal to or greater than the predetermined threshold value.

7. The touch sensor driving circuit of claim 1, wherein the sensing circuit includes:
a first-first differential amplifier configured to amplify and output a difference between a voltage of the second touch electrode sensed through the (n+1)^{th} RX wire and the first reference voltage;
a first-second differential amplifier configured to amplify and output a difference between a voltage of the second touch electrode sensed through the n^{th} RX wire and the first reference voltage;
a first-first amplifier configured to amplify and output a signal outputted from the first-first differential amplifier;
a first-second amplifier configured to amplify and output a signal outputted from the first-second differential amplifier;
a first-first integrator configured to integrate and output a difference between a signal amplified by the first-first amplifier and the second reference voltage lower than the first reference voltage;
a first-second integrator configured to integrate and output a difference between a signal amplified by the first-second amplifier and the first reference voltage; and
a second differential amplifier configured to amplify and output a difference between a signal outputted from the first-first integrator and a signal outputted from the first-second integrator, and
wherein the second touch electrode is among the second touch electrodes.

8. The touch sensor driving circuit of claim 1, wherein the sensing circuit includes:
a first-first differential amplifier configured to amplify and output a difference between a voltage of the second touch electrode sensed through the n^{th} RX wire and the second reference voltage;
a first-second differential amplifier configured to amplify and output a difference between a voltage of the second touch electrode sensed through the (n+1)^{th} RX wire and the first reference voltage;
a first-first amplifier configured to amplify and output a signal outputted from the first-first differential amplifier;
a first-second amplifier configured to amplify and output a signal outputted from the first-second differential amplifier;
a first-first integrator configured to integrate and output a difference between a signal amplified by the first-first amplifier and the first reference voltage;
a first-second integrator configured to integrate and output a difference between a signal amplified by the first-second amplifier and the first reference voltage; and
a second differential amplifier configured to amplify and output a difference between a signal outputted from the first-first integrator and a signal outputted from the first-second integrator, and
wherein the second touch electrode is among the second touch electrodes.

9. A touch sensor driving circuit, comprising:
a driving circuit configured to apply a driving signal to first touch electrodes arranged in a display area through a plurality of TX wires; and
a sensing circuit configured to sense voltages of second touch electrodes arranged in a first region and a second region within the display area through first RX wires and second RX wires, respectively, the voltages being generated by the driving signal,
wherein the sensing circuit is configured to sense a voltage difference between two RX wires respectively positioned closest to TX wires located at opposite outermost sides of the plurality of TX wires.

10. The touch sensor driving circuit of claim 9, wherein the driving circuit is configured to sequentially apply the driving signal from the TX wires located at opposite outermost sides of the plurality of TX wires toward TX wires located in a central region of the plurality of TX wires, and to apply the driving signal to each pair of TX wires located at the respective outermost sides.

11. The touch sensor driving circuit of claim 9, wherein the sensing circuit includes a plurality of first terminals to which the first RX wires are sequentially connected, and a plurality of second terminals to which the second RX wires are connected in reverse order.

12. A display device, comprising:
a display panel in which a plurality of pixels are arranged;
a touch panel disposed on the display panel, and including a plurality of first and second touch electrodes arranged in a display area divided into a first region and a second region, a plurality of TX wires connected to the first touch electrodes, and a plurality of RX wires connected to the second touch electrodes; and
a touch sensor driver connected to the plurality of first and second touch electrodes,
wherein the touch sensor driver includes:
a driving circuit configured to apply a driving signal to the first touch electrodes through the plurality of TX wires; and
a sensing circuit configured to sense, through first RX wires and second RX wires, a voltage of the second touch electrodes arranged in the first region and a voltage of the second touch electrodes arranged in the second region, respectively, the voltages being generated by the driving signal,
wherein the sensing circuit is configured to amplify or integrate a voltage difference between a voltage sensed through one n^{th} RX wire positioned closest to TX wires located at opposite outermost sides of the plurality of TX wires and a second reference voltage, and amplify or integrate a voltage difference between a voltage sensed through an (n+1)^{th} RX wire adjacent to the n^{th} RX wire and a first reference voltage different from the second reference voltage, where n is a natural number, and
wherein the first touch electrodes are among the plurality of first and second touch electrodes, and the second touch electrodes are among the plurality of first and second touch electrodes.

13. The display device of claim 12, wherein the sensing circuit includes:
a first-first differential amplifier configured to amplify and output a difference between a voltage of the second touch electrode sensed through the n^{th} RX wire and the first reference voltage;
a first-second differential amplifier configured to amplify and output a difference between a voltage of the second touch electrode sensed through the (n+1)^{th} RX wire and the first reference voltage;
a first-first amplifier configured to amplify and output a signal outputted from the first-first differential amplifier;
a first-second amplifier configured to amplify and output a signal outputted from the first-second differential amplifier;
a first-first integrator configured to integrate and output a difference between a signal amplified by the first-first amplifier and the second reference voltage higher than the first reference voltage;
a first-second integrator configured to integrate and output a difference between a signal amplified by the first-second amplifier and the first reference voltage; and
a second differential amplifier configured to amplify and output a difference between a signal outputted from the first-first integrator and a signal outputted from the first-second integrator, and
wherein the second touch electrode is among the second touch electrodes.

14. The display device of claim 13, wherein the first-first integrator includes an operational amplifier, a resistor, and a capacitor,
wherein the operational amplifier includes an inverting input terminal connected to the resistor and a non-inverting input terminal connected to a power line to which the second reference voltage is applied,
wherein the resistor is connected between the n^{th} RX wire and the inverting input terminal of the operational amplifier, and
wherein the capacitor is connected to the inverting input terminal of the operational amplifier.

15. The display device of claim 14, wherein the first-first integrator further includes a first switch and a second switch,
wherein the first switch is connected between the non-inverting input terminal of the operational amplifier and a power line to which the first reference voltage is applied, and
wherein the second switch is connected between the non-inverting input terminal of the operational amplifier and the power line to which the second reference voltage is applied.

16. The display device of claim 15, wherein each of the first and second switches includes a first contact point connected to the non-inverting input terminal of the operational amplifier, a second contact point connected to the power line to which the first reference voltage is applied, and a third contact point connected to the power line to which the second reference voltage is applied.

17. The display device of claim 16, wherein the driving circuit is configured to connect the first contact point to the second contact point when a magnitude of fringe capacitance generated in an RX wire is smaller than a predetermined threshold value, and connect the first contact point to the third contact point when the magnitude of the fringe capacitance generated in the RX wire is equal to or greater than the predetermined threshold value.

18. The display device of claim 12, wherein the sensing circuit includes:
a first-first differential amplifier configured to amplify and output a difference between a voltage of the second touch electrode sensed through the n^{th} RX wire and the second reference voltage;
a first-second differential amplifier configured to amplify and output a difference between a voltage of the second touch electrode sensed through the (n+1)^{th} RX wire and the first reference voltage;
a first-first amplifier configured to amplify and output a signal outputted from the first-first differential amplifier;
a first-second amplifier configured to amplify and output a signal outputted from the first-second differential amplifier;
a first-first integrator configured to integrate and output a difference between a signal amplified by the first-first amplifier and the first reference voltage;
a first-second integrator configured to integrate and output a difference between a signal amplified by the first-second amplifier and the first reference voltage; and
a second differential amplifier configured to amplify and output a difference between a signal outputted from the first-first integrator and a signal outputted from the first-second integrator, and
wherein the second touch electrode is among the second touch electrodes.

19. A display device, comprising:
a display panel in which a plurality of pixels are arranged;
a touch panel positioned on the display panel, and including a plurality of first and second touch electrodes arranged in a display area divided into a first region and a second region, a plurality of TX wires connected to the first touch electrodes, and a plurality of RX wires connected to the second touch electrodes; and
a touch sensor driver connected to the plurality of first and second touch electrodes,
wherein the touch sensor driver includes:
a driving circuit configured to apply a driving signal to the first touch electrodes through the plurality of TX wires; and
a sensing circuit configured to sense, through first RX wires and second RX wires, a voltage of the second touch electrodes arranged in the first region and a voltage of the second touch electrodes arranged in the second region, respectively, the voltages being generated by the driving signal,
wherein the sensing circuit is configured to sense a voltage difference between two RX wires respectively positioned closest to TX wires located at opposite outermost sides of the plurality of TX wires, and
wherein and the first touch electrodes are among the plurality of first and second touch electrodes, and the second touch electrodes are among the plurality of first and second touch electrodes.

20. The display device of claim 19, wherein the driving circuit is configured to sequentially apply the driving signal from the TX wires located at opposite outermost sides of the plurality of TX wires toward TX wires located in a central region of the plurality of TX wires, and to apply the driving signal to each pair of TX wires located at the respective outermost sides.

21. The display device of claim 19, wherein the sensing circuit includes a plurality of first terminals to which the first RX wires are sequentially connected, and a plurality of second terminals to which the second RX wires are connected in reverse order.

22. The display device of claim 12, wherein the sensing circuit includes:
a first-first differential amplifier configured to amplify and output a difference between a voltage of the second touch electrode sensed through the (n+1)^{th} RX wire and the first reference voltage;
a first-second differential amplifier configured to amplify and output a difference between a voltage of the second touch electrode sensed through the n^{th} RX wire and the first reference voltage;
a first-first amplifier configured to amplify and output a signal outputted from the first-first differential amplifier;
a first-second amplifier configured to amplify and output a signal outputted from the first-second differential amplifier;
a first-first integrator configured to integrate and output a difference between a signal amplified by the first-first amplifier and the second reference voltage lower than the first reference voltage;
a first-second integrator configured to integrate and output a difference between a signal amplified by the first-second amplifier and the first reference voltage; and
a second differential amplifier configured to amplify and output a difference between a signal outputted from the first-first integrator and a signal outputted from the first-second integrator, and
wherein the second touch electrode is among the second touch electrodes.
